(19) United States
(12) Patent Application Publication
(10) Pub. No.: US 2026/0109886 A1
(43) Pub. Date: Apr. 23, 2026

(54) BONDING SHEET

(71) Applicant: NITTO DENKO CORPORATION, Ibaraki-shi, Osaka (JP)

(72) Inventors: Masatoshi KATO, Ibaraki-shi, Osaka (JP); Tsubasa OMURA, Ibaraki-shi, Osaka (JP); Yuichiro SHISHIDO, Ibaraki-shi, Osaka (JP); Naofumi KOSAKA, Ibaraki-shi, Osaka (JP)

(21) Appl. No.: 19/111,385

(22) PCT Filed: Sep. 27, 2023
(86) PCT No.: PCT/JP2023/035303

§ 371 Date: Mar. 13, 2025

(30) Foreign Application Priority Data
Sep. 30, 2022 (JP) 2022-158534

(51) Int. Cl. C09J 7/30; C08K 3/105; C08K 3/11; C08K 5/092; C09J 9/02; C09J 163/00

(52) U.S. Cl. CPC C09J 7/30; C08K 3/105; C08K 3/11; C08K 5/092; C09J 9/02; C09J 163/00; C08K 2201/005; C09J 2203/326; C09J 2301/314; C09J 2301/408; C09J 2463/00

(57) ABSTRACT

A bonding sheet includes a resin component and a solder particle. Both an average primary particle size of the solder particle and an average secondary particle size of the solder particle are 7 μm or less.

### TECHNICAL FIELD

The present invention relates to a bonding sheet.

### BACKGROUND ART

Conventionally, in bonding between terminals of two wiring circuit boards which are disposed spaced apart in a thickness direction, a bonding sheet has been used.

Specifically, first, a first wiring circuit board including a plurality of first electrodes disposed in a plane direction, and a second wiring circuit board including a plurality of second electrodes disposed in the plane direction are prepared. Next, a bonding sheet is disposed so as to cover the surface on which the first electrode of the first wiring circuit board is provided, and furthermore, the second wiring circuit board is disposed on the surface of the bonding sheet so as to cover the surface on which the second electrode of the second wiring circuit board is provided. That is, the first electrode and the second electrode are disposed to face each other in the thickness direction. Next, the bonding sheet is heated. Thus, solder particles included in the bonding sheet are melted, and gather between the first electrode and the second electrode (self-aggregation), thereby forming a solder portion which electrically connects the first electrode to the second electrode.

As such a bonding sheet, for example, an anisotropic electrically conductive bonding film including a solid epoxy resin, a liquid epoxy resin, a flux compound, and solder particles having an average particle size of 7.1 μm has been proposed (ref: for example, Example 1 of Patent Document 1).

### CITATION LIST

### Patent Document

Patent Document 1: Japanese Unexamined Patent Publication No. 2021-68842

### SUMMARY OF THE INVENTION

### Problem to be Solved by the Invention

On the other hand, since the average particle size of the solder particles of Patent Document 1 is as large as 7.1 μm, unevenness may occur in the above-described self-aggregation. Then, there is a problem that reliability is lowered.

The present invention provides a bonding sheet having excellent reliability.

### Means for Solving the Problem

The present invention [1] includes a bonding sheet including a resin component and a solder particle, wherein both an average primary particle size of the solder particle and an average secondary particle size of the solder particle are 7 μm or less.

The present invention [2] includes the bonding sheet described in the above-described [1] further including flux.

The present invention [3] includes the bonding sheet described in the above-described [1], wherein the resin component includes a thermoplastic resin, and the thermoplastic resin has a softening point of 110° C. or more.

The present invention [4] includes the bonding sheet described in any one of the above-described [1] to [3], wherein the viscosity of the resin component at a melting point of the solder particle is 5000 mPa·s or less.

The present invention [5] includes the bonding sheet described in the above-described [1], wherein the resin component includes a thermoplastic resin and a thermosetting resin, the thermoplastic resin is solid at 25° C., and the thermosetting resin is liquid at 25° C.

The present invention [6] includes the bonding sheet described in the above-described [1], wherein both the average primary particle size of the solder particle and the average secondary particle size of the solder particle are 5 μm or less.

The present invention [7] includes the bonding sheet described in any one of the above-described [1] to [6], wherein the bonding sheet has a thickness of 15 μm or less.

### Effect of the Invention

The bonding sheet of the present invention includes the solder particles, and both the average primary particle size and the average secondary particle size of the solder particles are 7 μm or less. Thus, it is possible to improve reliability.

### BRIEF DESCRIPTION OF THE DRAWINGS

FIGS. 1A and 1B show one embodiment of a method for producing a bonding sheet:

FIG. 1A illustrating a preparation step of preparing a release liner and

FIG. 1B illustrating a disposition step of disposing a bonding sheet on one surface of the release liner in a thickness direction.

FIGS. 2A to 2E show one embodiment of a method for using a bonding sheet:

FIG. 2A illustrating a first step of preparing a first substrate and a second substrate,

FIG. 2B illustrating a second step of preparing a bonding sheet,

FIG. 2C illustrating a third step of laminating the first substrate, the bonding sheet, and the second substrate,

FIG. 2D illustrating a fourth step of thermo-compressively bonding the first substrate and the second substrate to the bonding sheet, and

FIG. 2E illustrating a fifth step of forming an adhesive layer solder-bonding the first substrate and the second substrate to the bonding sheet.

FIGS. 3A and 3B show schematic views for illustrating a columnar solder portion in an adhesive layer:

FIG. 3A illustrating an embodiment in which columnar solder portions disposed adjacent to each other in a plane direction are electrically connected and

FIG. 3B illustrating an embodiment in which the columnar solder portions electrically connected to each other are not formed.

FIG. 4 shows an observation photograph of a digital microscope as for a bonding sheet of Example 1.

FIG. 5 shows an observation photograph of a digital microscope as for a bonding sheet of Example 2.

FIG. 6 shows an observation photograph of a digital microscope as for a bonding sheet of Example 3.

FIG. 7 shows an observation photograph of a digital microscope as for a bonding sheet of Comparative Example 1.

FIG. 8 shows an observation photograph of a digital microscope as for a bonding sheet of Comparative Example 2.

### DESCRIPTION OF EMBODIMENTS

A bonding sheet is formed from a bonding sheet composition into a sheet shape.

The bonding sheet composition includes a resin component and solder particles. That is, the bonding sheet includes the resin component and the solder particles.

### <Resin Component>

The resin component includes a thermoplastic resin and a curing resin.

### [Thermoplastic Resin]

Examples of the thermoplastic resin include thermoplastic epoxy resins, thermoplastic phenol resins, phenoxy resins, polyolefin (for example, polyethylene, polypropylene, ethylene-propylene copolymers, etc.), thermoplastic acrylic resins, thermoplastic polyester, polyvinyl acetate, ethylene-vinyl acetate copolymers, polyvinyl chloride, polystyrene, polyacrylonitrile, polyamide (nylon (registered trademark)), polycarbonate, polyacetal, polyethylene terephthalate, polyphenylene oxide, polyphenylene sulfide, polysulfone, polyether sulfone, polyether ether ketone, polyallyl sulfone, thermoplastic polyimide, thermoplastic polyurethane, polyaminobismaleimide, polyamideimide, polyetherimide, bismaleimide triazine resins, polymethylpentene, fluoride resins, liquid crystal polymers, olefin-vinyl alcohol copolymers, ionomers, polyarylate, acrylonitrile-ethylene-styrene copolymers, acrylonitrile-butadiene-styrene copolymers, acrylonitrile-styrene copolymers, and butadiene-styrene copolymers. As the thermoplastic resin, preferably, a thermoplastic epoxy resin and a thermoplastic phenol resin are used.

Examples of the thermoplastic epoxy resin include thermoplastic bisphenol-type epoxy resins (for example, thermoplastic bisphenol A-type epoxy resins, thermoplastic bisphenol F-type epoxy resins, and thermoplastic bisphenol S-type epoxy resins), thermoplastic novolac-type epoxy resins (for example, thermoplastic phenol novolac-type epoxy resins, thermoplastic cresol novolac-type epoxy resins, and thermoplastic biphenyl-type epoxy resins), thermoplastic naphthalene-type epoxy resins, thermoplastic fluorene-type epoxy resins (for example, bisarylfluorene-type epoxy resins), and thermoplastic triphenylmethane-type epoxy resins (for example, trishydroxyphenylmethane-type epoxy resins). As the thermoplastic epoxy resin, preferably, a thermoplastic bisphenol-type epoxy resin is used. As the thermoplastic epoxy resin, more preferably, a thermoplastic bisphenol A-type epoxy resin is used.

Further, these thermoplastic resins may be in any form of solid, semi-solid, and liquid at normal temperature (25° C.).

Being solid at 25° C. is a property which does not flow at 25° C., and does not have viscosity. In addition, being liquid at 25° C. is a property which includes a liquid and a fluid at 25° C., and has the viscosity (hereinafter, the same applies).

As the thermoplastic resin, preferably, a solid thermoplastic resin is used.

Further, a softening point of the thermoplastic resin is, for example, 110° C. or more, preferably 120° C. or more, more preferably above 120° C., further more preferably 125° C. or more, and for example, 230° C. or less, preferably 200° C. or less, more preferably below 150° C., further more preferably 140° C. or less.

When the above-described softening point is the above-described lower limit or more, it is possible to more reliably make both an average primary particle size and an average secondary particle size of the solder particles to be described later 7 μm or less.

Specifically, when the above-described softening point is the above-described lower limit or more, the thermoplastic resin can suppress aggregation of the solder particles in a disposition step of a method for producing a bonding sheet to be described later. As a result, it is possible to more reliably make both the average primary particle size and the average secondary particle size of the solder particles to be described later 7 μm or less.

The above-described softening point can be measured with a thermomechanical analyzer.

These thermoplastic resins may be used alone or in combination of two or more.

A content ratio of the thermoplastic resin is, for example, 30 parts by mass or more, preferably 40 parts by mass or more, and for example, 70 parts by mass or less, preferably 60 parts by mass or less with respect to 100 parts by mass of the resin component.

### [Curing Resin]

Examples of the curing resin include thermosetting resins. Examples of the thermosetting resin include thermosetting epoxy resins, urea resins, melamine resins, diallyl phthalate resins, silicone resins, phenol resins, thermosetting acrylic resins, thermosetting polyester, thermosetting polyimide, and thermosetting polyurethane. As the curing resin, preferably, a thermosetting epoxy resin is used.

Examples of the thermosetting epoxy resin include thermosetting bisphenol-type epoxy resins (for example, thermosetting bisphenol A-type epoxy resins, thermosetting bisphenol F-type epoxy resins, and thermosetting bisphenol S-type epoxy resins), thermosetting novolac-type epoxy resins (for example, thermosetting phenol novolac-type epoxy resins, thermosetting cresol novolac-type epoxy resins, and thermosetting biphenyl-type epoxy resins), thermosetting naphthalene-type epoxy resins, thermosetting fluorene-type epoxy resins (for example, thermosetting bisarylfluorene-type epoxy resins), and thermosetting triphenylmethane-type epoxy resins (for example, thermosetting trishydroxyphenylmethane-type epoxy resins). As the thermosetting epoxy resin, preferably, a thermosetting bisphenol-type epoxy resin is used. As the thermosetting epoxy resin, more preferably, a thermosetting bisphenol A-type epoxy resin is used.

Further, these thermosetting resins may be in any form of solid, semi-solid, and liquid at normal temperature (25° C.).

As the thermosetting resin, preferably, a liquid thermosetting resin is used.

Then, the resin component preferably includes a solid thermoplastic resin and a liquid thermosetting resin. When the resin component includes the solid thermoplastic resin and the liquid thermosetting resin, moldability and adhesive strength as a pressure-sensitive adhesive sheet are excellent.

The resin component more preferably consists of a solid thermoplastic resin and a liquid thermosetting resin.

These curing resins may be used alone or in combination of two or more.

The content ratio of the curing resin is, for example, 30 parts by mass or more, preferably 40 parts by mass or more, and for example, 70 parts by mass or less, preferably 60 parts by mass or less with respect to 100 parts by mass of the resin component.

Then, the viscosity of the resin component at a melting point of the solder particles to be described later is, for example, 1 mPa·s or more, preferably 100 mPa·s or more, and for example, 5000 mPa·s or less, preferably 2000 mPa·s or less, more preferably 1000 mPa·s or less, further more preferably 500 mPa·s or less.

When the above-described viscosity is the above-described lower limit or more and the above-described upper limit or less, it is possible to reduce the non-integrated solder particles (described later). As a result, it is possible to improve productivity.

The viscosity can be measured with a rheometer. In addition, measurement of the viscosity is described in detail in Examples to be described later.

Further, the content ratio of the resin component is, for example, 20% by mass or more, preferably 30% by mass or more, and for example, 60% by mass or less, preferably 40% by mass or less with respect to the bonding sheet composition (bonding sheet).

In addition, in the resin component, a mass ratio of the curing resin to the thermoplastic resin is, for example, 0.6 or more, preferably 0.9 or more, and for example, 1.5 or less, preferably 1.1 or less.

### <Solder Particles>

Examples of a solder material which forms the solder particles include solder materials without containing lead (lead-free solder materials) from the viewpoint of environmental suitability. Specifically, examples of the solder material include tin and tin alloys. Examples of the tin alloy include tin-bismuth alloys (Sn—Bi), tin-silver-copper alloys (Sn—Ag—Cu), and tin-silver alloys (Sn—Ag).

The content ratio of the tin in the tin-silver alloy is, for example, 90% by mass or more, preferably 95% by mass or more. Further, the content ratio of the silver in the tin-silver alloy is, for example, 10% by mass or less, preferably 5% by mass or less.

The content ratio of the tin in the tin-silver-copper alloy is, for example, 90% by mass or more, preferably 95% by mass or more. Further, the content ratio of the silver in the tin-silver-copper alloy is, for example, 10% by mass or less, preferably 5% by mass or less. Further, the content ratio of the copper in the tin-silver-copper alloy is, for example, 1% by mass or less, preferably 0.5% by mass or less.

Further, the content ratio of the tin in the tin-bismuth alloy is, for example, 30% by mass or more, preferably 40% by mass or more. The content ratio of the bismuth in the tin-bismuth alloy is, for example, 70% by mass or less, preferably 60% by mass or less.

As the solder material, preferably, a tin-silver alloy (Sn—Ag) and a tin-silver-copper alloy (Sn—Ag—Cu) are used.

The melting point of the solder material (that is, the melting point of the solder particles) is, for example, 260° C. or less, preferably 235° C. or less, and for example, 100° C. or more, preferably 130° C. or more. The melting point is determined by differential scanning calorimetry (DSC) (hereinafter, the same applies).

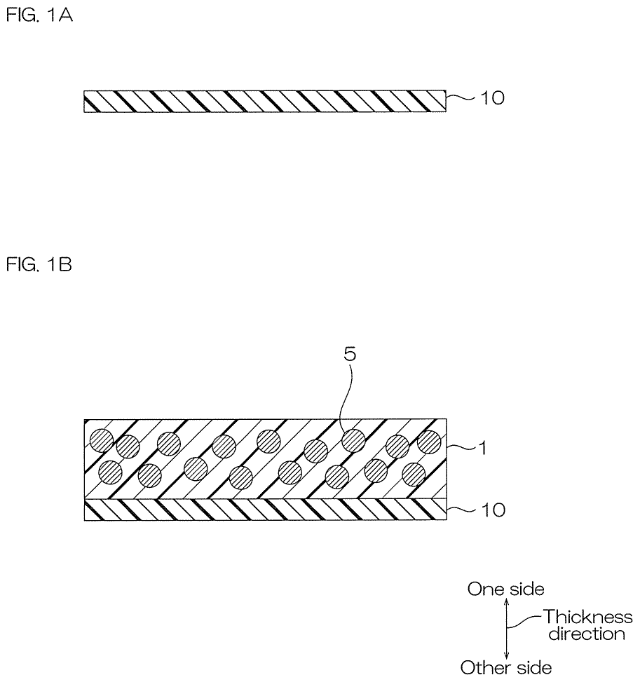

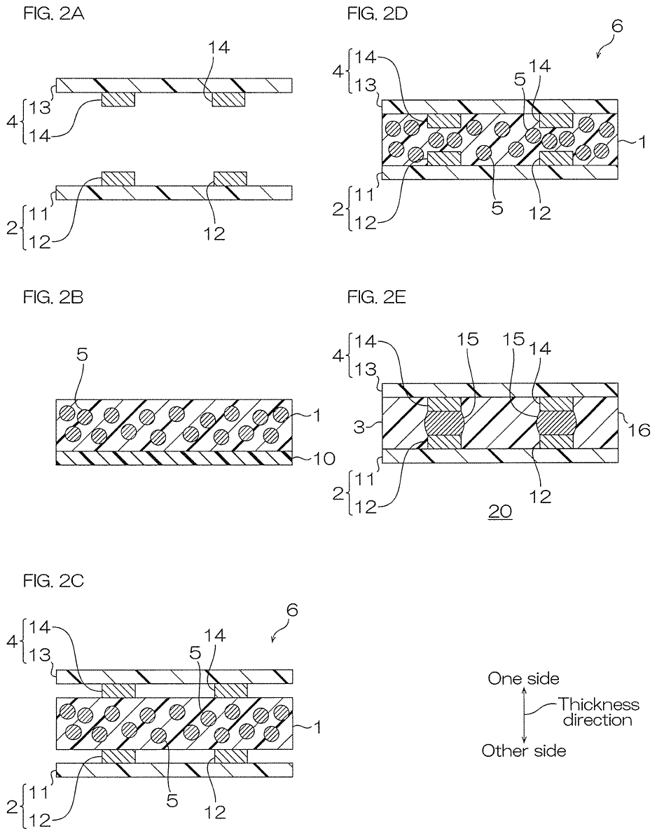

A shape of the solder particles is not particularly limited, and examples thereof include spherical shapes, plate shapes, and needle shapes. As the shape of the solder particles, preferably, a spherical shape is used. In FIGS. 1B, 2B, 2C, and 2D, the shape of the solder particles is shown as the spherical shape, and the shape of the solder particles is not limited to this.

The surfaces of the solder particles are generally covered with an oxide film made of an oxide of the solder material. A thickness of the oxide film is, for example, 1 nm or more, and for example, 20 nm or less.

In addition, the solder particles may be secondary particles by a part or all of the solder particles being aggregated in a preparation step of the bonding sheet composition to be described later and/or a disposition step of a method for producing a bonding sheet to be described later. That is, the bonding sheet includes primary particles of the solder particles and/or the secondary particles of the solder particles.

Then, both the average primary particle size of the solder particles and the average secondary particle size of the solder particles are 7 μm or less, from the viewpoint of a reduction in size and height and reliability, preferably 5 μm or less, and for example, 0.1 μm or more, preferably 0.5 μm or more.

Specifically, the primary particles are the smallest unit of particles and independent particles without aggregation. The average primary particle size of the solder particles is, 7 μm or less, from the viewpoint of the reduction in size and height and the reliability, preferably 5 μm or less, and for example, 0.1 μm or more, preferably 0.5 μm or more.

Further, the secondary particles are particles obtained by aggregating the primary particles. The average secondary particle size is larger than the average primary particle size, and specifically, 7 μm or less, from the viewpoint of the reduction in size and height and the reliability, preferably, 5 μm or less, and for example, 1 μm or more.

As described above, the bonding sheet includes the primary particles of the solder particles and/or the secondary particles of the solder particles. That is, the bonding sheet includes only the primary particles of the solder particles, or includes only the secondary particles of the solder particles, or includes the primary particles of the solder particles and the secondary particles of the solder particles. In any case, both the average primary particle size of the solder particles and the average secondary particle size of the solder particles are 7 μm or less.

When both the above-described average primary particle size and the above-described average secondary particle size are the above-described upper limit or less, it is possible to suppress unevenness in the self-aggregation to be described later. As a result, it is possible to improve the reliability.

On the other hand, when at least any one of the above-described average primary particle size and the above-described average secondary particle size is above the above-described upper limit, it is not possible to suppress the unevenness in the self-aggregation to be described later. As a result, the reliability is lowered.

The above-described average primary particle size can be measured with a laser diffraction particle size distribution measuring device. Further, the method for measuring the above-described average secondary particle size is described in detail in Examples to be described later.

These solder particles may be used alone or in combination of two or more.

The content ratio of the solder particles is, for example, 50% by mass or more, preferably 55% by mass or more, and for example, 80% by mass or less, preferably 60% by mass or less with respect to the bonding sheet composition (bonding sheet).

### <Flux>

The bonding sheet composition preferably includes flux. That is, the bonding sheet preferably includes the flux. The flux is a component for removing an oxide film on the surfaces of the solder particles (oxide film made of an oxide of the solder material).

Examples of the material for the flux include organic acid salts. Examples of the organic acid salt include organic acids, quinolinol derivatives, and metal carbonyl acid salts. Examples of the organic acid include aliphatic carboxylic acids and aromatic carboxylic acids. Examples of the aliphatic carboxylic acid include aliphatic dicarboxylic acids. Specific examples of the aliphatic dicarboxylic acid include adipic acid, malic acid, malonic acid, succinic acid, glutaric acid, pimelic acid, suberic acid, and sebacic acid. Examples of the aromatic carboxylic acid include benzoic acid, 2-phenoxybenzoic acid, phthalic acid, diphenylacetic acid, trimellitic acid, and pyromellitic acid. As the material for the flux, preferably, an organic acid is used. As the material for the flux, more preferably, a malic acid is used.

The melting point of the flux is, for example, 250° C. or less, preferably 180° C. or less, more preferably 160° C. or less, and for example, 100° C. or more, preferably 120° C. or more, more preferably 130° C. or more.

The shape of the flux is not particularly limited, and examples thereof include plate shapes, needle shapes, and spherical shapes.

In addition, the flux can be dissolved in a known solvent, and used as a solution of the flux. The solid content concentration of the solution of the flux is, for example, 10% by mass or more, and for example, 40% by mass or less.

The flux may be used alone or in combination of two or more.

The content ratio of the flux is, for example, 1% by mass or more, preferably 5% by mass or more, and for example, 20% by mass or less, preferably 10% by mass or less with respect to the bonding sheet composition (bonding sheet).

### <Additive>

The bonding sheet composition may contain, if necessary, an additive (for example, a curing agent, a curing accelerator, and a silane coupling agent) at an appropriate ratio.

### <Preparation of Bonding Sheet Composition>

The bonding sheet composition is prepared by mixing the resin component, the solder particles, the flux to be blended if necessary, and the additive to be blended if necessary, and stirring the mixture if necessary.

In the above-described preparation, when the solder particles are mixed without stirring, a large portion of the solder particles is aggregated to be the secondary particles. On the other hand, in the above-described preparation, when the solder particles are mixed by stirring, the solder particles remain as the primary particles.

Further, the bonding sheet composition can be blended into a known solvent, thereby preparing the bonding sheet composition as a varnish. The solid content concentration of the varnish of the bonding sheet composition is, for example, 50% by mass or more, preferably 60% by mass or more, and for example, 80% by mass or less.

### <Method for Producing Bonding Sheet>

One embodiment of a method for producing a bonding sheet is described in detail with reference to FIGS. 1A and 1B.

In FIGS. 1A and 1B, an up-down direction on the plane of the sheet is the up-down direction (thickness direction). Further, an upper side on the plane of the sheet is the upper side (one side in the thickness direction) and a lower side on the plane of the sheet is the lower side (other side in the thickness direction). A right-left direction on the plane of the sheet and a depth direction are a plane direction perpendicular to the up-down direction. Specifically, the directions are in conformity with direction arrows of each view.

The method for producing a bonding sheet includes a preparation step of preparing a release liner 10 and a disposition step of disposing a bonding sheet 1 on one surface of the release liner 10 in the thickness direction.

### [Preparation Step]

In the preparation step, as shown in FIG. 1A, the release liner 10 is prepared.

The release liner is a film for covering and protecting the bonding sheet 1. The release liner 10 has a film shape.

The release liner 10 is, for example, a plastic substrate (plastic film). Examples of the plastic substrate include polyester sheets (polyethylene terephthalate (PET) sheets), polyolefin sheets (for example, polyethylene sheets, polypropylene sheets), polyvinyl chloride sheets, polyimide sheets, and polyamide sheets (nylon sheets). The surface (one surface in the thickness direction) of the release liner 10 may be also subjected to a surface treatment such as silicone treatment.

The thickness of the release liner 10 is, for example, 1 μm or more, and for example, 100 μm or less.

### [Disposition Step]

In the disposition step, as shown in FIG. 1B, the bonding sheet 1 is disposed on one surface of the release liner 10 in the thickness direction.

In order to dispose the bonding sheet 1 on one surface of the release liner 10 in the thickness direction, the bonding sheet composition (varnish of the bonding sheet composition) is coated onto one surface of the release liner 10 in the thickness direction, and thereafter, dried if necessary.

As drying conditions, a drying temperature is, for example, 40° C. or more, and for example, 100° C. or less. Drying time is, for example, 1 minute or more, and for example, 60 minutes or less.

Further, by heating during the above-described drying, the resin component flows, and solder particles 5 may flow according to its movement. Then, a part or all of the solder particles 5 aggregate to be the secondary particles. As the drying temperature increases, the solder particles 5 tend to aggregate, and by increasing a softening point of the above-described thermoplastic resin, it is possible to suppress the flow of the resin component. Even when the drying temperature is high, it is possible to suppress the aggregation of the solder particles 5. Preferably, the drying temperature is adjusted so that a difference between the softening point of the thermoplastic resin and the drying temperature (softening point of the thermoplastic resin-drying temperature) is, for example, 50° C. or more, preferably 60° C. or more.

As described above, it is possible to produce the bonding sheet 1 disposed on one surface of the release liner 10 in the thickness direction.

Such a bonding sheet 1 includes the resin component, and the solder particles 5 dispersed in the resin component (the primary particles and the secondary particles of the solder particles 5). In FIG. 1B, the solder particles 5 are described without distinguishing the primary particles from the secondary particles (hereinafter, the same applies).

The thickness of the bonding sheet 1 is, from the viewpoint of the reduction in size and height, for example, 15 μm or less, preferably 7 μm or less, more preferably 6 μm or less, and for example, 1 μm or more.

### <Method for Using Bonding Sheet>

One embodiment of a method for using a bonding sheet (method for producing a connecting structure) is described in detail with reference to FIGS. 2A to 2E.

The method for using a bonding sheet (method for producing a connecting structure) includes a first step of preparing a first substrate 2 and a second substrate 4, a second step of preparing the bonding sheet 1, a third step of laminating the first substrate 2, the bonding sheet 1, and the second substrate 4, a fourth step of thermo-compressively bonding the first substrate 2 and the second substrate 4 to the bonding sheet 1, and a fifth step of forming an adhesive layer 3 which solder-bonds the first substrate 2 and the second substrate 4 to the bonding sheet 1.

### [First Step]

In the first step, as shown in FIG. 2A, the first substrate 2 and the second substrate 4 are prepared.

The first substrate 2 has a flat plate shape.

The first substrate 2 includes a first wiring circuit board 11, and a plurality of first electrodes 12 arranged in the plane direction of the first wiring circuit board 11. In other words, the first substrate 2 includes the first wiring circuit board 11, and the plurality of first electrodes 12 provided on the surface (one surface in the thickness direction) of the first wiring circuit board 11.

The first wiring circuit board 11 is, for example, formed of an insulating material and a semiconductor material.

The thickness of the first wiring circuit board 11 is, for example, 5 μm or more, and for example, 1000 μm or less.

The first electrode 12 is made of a metal.

The first electrode 12 is arranged as a dot pattern in the first substrate 2.

Specifically, the first electrode 12 has a circular shape when viewed from the top. Further, the plurality of first electrodes 12 are evenly disposed in alignment in the plane direction.

The thickness of the first electrode 12 is, for example, 0 μm or more, preferably 0.001 μm or more, and for example, 5 μm or less. When the surface of the first substrate 2 and the surface of the first electrode 12 are matched, the thickness of the first electrode 12 is 0 μm.

A diameter of the first electrode 12 is, for example, 100 μm or less, preferably 20 μm or less, and for example, 1 μm or more.

Further, in the plane direction, a distance (pitch) of the first electrodes 12 adjacent to each other is, for example, 3 μm or more, preferably 5 μm or more, and for example, 200 μm or less, preferably 100 μm or less, more preferably 40 μm or less.

The second substrate 4 has a flat plate shape.

The second substrate 4 includes a second wiring circuit board 13 and a plurality of second electrodes 14 arranged in the plane direction of the second wiring circuit board 13. In other words, the second substrate 4 includes the second wiring circuit board 13, and the plurality of second electrodes 14 provided on the surface (the other surface in the thickness direction) of the second wiring circuit board 13.

The second wiring circuit board 13 is, for example, formed of an insulating material and a semiconductor material.

The thickness of the second wiring circuit board 13 is, for example, 5 μm or more, and for example, 1000 μm or less.

The second electrode 14 is made of a metal.

The second electrode 14 is arranged as the dot pattern in the second substrate 4.

Specifically, the second electrode 14 has a circular shape when viewed from the top. Further, the plurality of second electrodes 14 are evenly disposed in alignment in the plane direction.

The thickness of the second electrode 14 is, for example, 0 μm or more, preferably 0.001 μm or more, and for example, 5 μm or less. Further, when the surface of the second substrate 4 and the surface of the second electrode 14 are matched, the thickness of the second electrode 14 is 0 μm.

The diameter of the second electrode 14 is, for example, 100 μm or less, preferably 20 μm or less, and for example, 1 μm or more.

Further, in the plane direction, the distance (pitch) of the second electrodes 14 adjacent to each other is the same as the distance (pitch) of the first electrodes 12 adjacent to each other in the above-described plane direction.

### [Second Step]

In the second step, as shown in FIG. 2B, the bonding sheet 1 is prepared. The bonding sheet 1 includes the solder particles 5. As described above, the solder particles 5 in the bonding sheet 1 are the primary particles or the secondary particles.

### [Third Step]

In the third step, as shown in FIG. 2C, the first substrate 2, the bonding sheet 1, and the second substrate 4 are laminated.

Specifically, the first substrate 2 and the second substrate 4 are brought into close contact with the bonding sheet 1, and then, the first substrate 2 and the second substrate 4 are brought into contact with the bonding sheet 1. More specifically, one surface in the thickness direction of the first substrate 2 is brought into contact with the other surface in the thickness direction of the bonding sheet 1, and the other surface in the thickness direction of the second substrate 4 is brought into contact with one surface in the thickness direction of the bonding sheet 1 so that the first electrode 12 and the second electrode 14 face each other in the thickness direction.

Thus, the first substrate 2, the bonding sheet 1, and the second substrate 4 are laminated, thereby producing a laminate 6.

### [Fourth Step]

In the fourth step, as shown in FIG. 2D, the first substrate 2 and the second substrate 4 are thermo-compressively bonded to the bonding sheet 1.

Specifically, the first substrate 2 and the second substrate 4 are pressed (thermo-compressively bonded) to the bonding sheet 1, while the laminate 6 is heated.

The temperature of thermocompression bonding is a temperature below the melting point of the solder particles 5. Specifically, the temperature of the thermocompression bonding is, for example, below 100° C., preferably 80° C. or less, and for example, 40° C. or more, preferably 60° C. or more. The pressure of the thermocompression bonding is, for example, 0.001 MPa or more, preferably 0.005 MPa or more, more preferably 0.01 MPa or more, and for example, 10 MPa or less, preferably 5 MPa or less, more preferably 1 MPa or less.

Thus, the first electrode 12 of the first substrate 2 is embedded in the bonding sheet 1, and one surface in the thickness direction of the first substrate 2 is covered with the bonding sheet 1. Further, the second electrode 14 of the second substrate 4 is embedded in the bonding sheet 1, and the other surface in the thickness direction of the second substrate 4 is covered with the bonding sheet 1.

### [Fifth Step]

In the fifth step, as shown in FIG. 2E, the adhesive layer 3 which solder-bonds the first substrate 2 and the second substrate 4 to the bonding sheet 1 is formed.

Specifically, the laminate 6 is heated.

A heating temperature is a temperature which is the melting point of the solder particles 5 or more. Specifically, the heating temperature is, for example, 100° C. or more, preferably 130° C. or more, and for example, 300° C. or less, preferably 280° C. or less, more preferably 270° C. or less.

The solder particles 5 are melted by such heating. The melted solder particles 5 aggregate between the first electrode 12 and the second electrode 14 facing each other in the thickness direction (self-aggregation), thereby forming a columnar solder portion 15. On the other hand, the resin component in the bonding sheet 1 is pushed out by the self-aggregating solder particles 5, and moves to the periphery of the columnar solder portion 15. Thereafter, when the resin component includes the thermosetting resin, the thermosetting resin is thermally cured to be a cured resin 16 which bonds the first substate 2 to the second substrate 4.

As described above, a large portion of the melted solder particles 5 is used to form the columnar solder portion 15. However, there is a case where a portion of the melted solder particles 5 and/or the solder particles 5 which are not melted are/is not used to form the columnar solder portion 15, and remain(s) to be dispersed in the resin component to be the non-integrated solder particles.

Thus, the adhesive layer 3 including the columnar solder portion 15 and the cured resin 16 is formed.

The thickness of the adhesive layer 3 is, from the viewpoint of the reduction in size and height, below 15 μm, preferably 10 μm or less, more preferably below 10 μm, further more preferably 5 μm or less, and for example, 1 μm or more.

As described above, a connecting structure 20 is produced.

The connecting structure 20 includes the first substrate 2, the second substrate 4 disposed spaced apart in the thickness direction, and the adhesive layer 3 interposed between the first substrate 2 and the second substrate 4. In other words, the connecting structure 1 includes the first substrate 2, the adhesive layer 3, and the second substrate 4 in order toward one side in the thickness direction. More specifically, the connecting structure 1 includes the first substrate 2, the adhesive layer 3 which is directly disposed on the upper surface (one surface in the thickness direction) of the first substrate 2, and the second substrate 4 which is directly disposed on the upper surface (one surface in the thickness direction) of the adhesive layer 3.

The adhesive layer 3 bonds the first substrate 2 to the second substrate 4. Specifically, the adhesive layer 3 is bonded to the surface of the first substrate 2 except for the first electrode 12. Further, the adhesive layer 3 is bonded to the surface of the second substrate 4 except for the second electrode 14.

Further, the columnar solder portion 15 electrically connects the first electrode 12 and the second electrode 14 facing each other in the thickness direction. Further, the columnar solder portion 15 has a columnar shape (specifically, cylindrical shape), and is disposed between the first electrode 12 and the second electrode 14 to be in contact with them.

In the above-described method for using a bonding sheet (method for producing a connecting structure), the above-described bonding sheet is used. Therefore, it is possible to suppress the unevenness in the above-described self-aggregation. As a result, it is possible to improve the reliability.

### <Function and Effect>

The bonding sheet 1 includes the solder particles 5, and both the average primary particle size and the average secondary particle size of the solder particles 5 are 7 un or less. Therefore, it is possible to suppress the unevenness in the above-described self-aggregation. As a result, it is possible to improve the reliability.

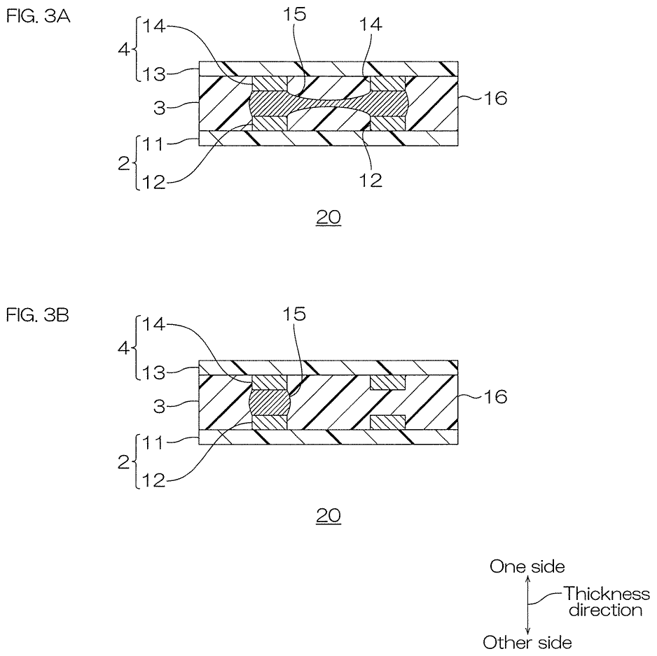

Specifically, of the average primary particle size and the average secondary particle size of the solder particles 5, when at least any one of them is above 7 μm, the self-aggregation of the solder particles 5 becomes uneven. Then, when the space between the two first electrodes 12 adjacent to each other in the plane direction is narrow, in the above-described fifth step, as shown in FIG. 3A, the solder particles 5 locally self-aggregate between the two first electrodes 12 adjacent to each other in the plane direction, so that the columnar solder portions 15 adjacent to each other in the plane direction are electrically connected (that is, the two first electrodes 12 adjacent to each other are electrically connected (bridged)). Since the two first electrodes 12 adjacent to each other are electrically connected, the two first electrodes 12 are short-circuited, and the reliability is lowered.

Further, when the self-aggregation of the solder particles 5 is uneven, as shown in FIG. 3B, there may be a case where the solder particles 5 do not self-aggregate between the first electrode 12 and the second electrode 14 on the right side, while the solder particles 5 locally self-aggregate between the first electrode 12 and the second electrode 14 on the left side, so that the columnar solder portion 15 cannot be formed. As a result, a connection failure occurs, and the reliability is lowered.

On the other hand, in the bonding sheet 1, since both the average primary particle size and the average secondary particle size of the solder particles 5 are 7 μm or less, it is possible to suppress the unevenness in the above-described self-aggregation. Thus, it is possible to suppress the bridge and the connection failure described above, and the reliability is improved.

### Modified Examples

In each modified example, the same reference numerals are provided for members and steps corresponding to each of those in one embodiment, and their detailed description is omitted. Further, each modified example can achieve the same function and effect as that of one embodiment unless otherwise specified. Furthermore, one embodiment and each modified example can be appropriately used in combination.

Further, in the above-described description, the first electrode 12 and the second electrode 14 are arranged as the dot pattern. However, the disposition of the first electrode 12 and the second electrode 14 is not limited to this.

Further, in the above-described description, the first electrode 12 and the second electrode 14 have a circular shape when viewed from the top. However, the shape of the first electrode 12 and the second electrode 14 is not limited to this. For example, it may have a rectangular shape when viewed from the top.

Further, in the above-described description, the second substrate 4 has a flat plate shape. However, the shape of the second substrate 4 is not limited to this. For example, it may have a shape having a chip component (for example, mini/microLED).

Further, in the above-described description, in the third step, the first substrate 2 and the second substrate 4 are brought into close contact with the bonding sheet 1, and the first substrate 2 and the second substrate 4 are brought into contact with the bonding sheet 1. Alternatively, first, the bonding sheet 1 is disposed on one surface in the thickness direction (the surface where the first electrode 12 is provided) of the first substrate 2, and next, the second substrate 4 is also disposed on one surface in the thickness direction of the bonding sheet 1 so that the first electrode 12 and the second electrode 14 face each other. Further, before disposing the second substrate 4, one surface in the thickness direction of the bonding sheet 1 can be also subjected to a surface treatment (for example, surface treatment by coating a silica filler).

Further, in the above-described description, the fourth step and the fifth step are carried out as separate steps. Alternatively, it is also possible to carry out the fourth step and the fifth step simultaneously. In such a case, the thermocompression bonding is carried out at the pressure in the fourth step and the temperature in the fifth step.

Further, in the above-described description, in the fourth step, the first substrate 2 and the second substrate 4 are thermo-compressively bonded to the bonding sheet 1. Among others, when the second substrate 4 is the chip component, it is also possible to produce the connecting structure 20 by reflow or vacuum reflow without carrying out the thermocompression bonding.

### EXAMPLES

Next, the present invention is further described based on Examples and Comparative Examples. The present invention is however not limited by Examples below. All designations of “part” or “parts” and “%” mean part or parts by mass and % by mass, respectively, unless otherwise particularly specified. Further, the specific numerical values in mixing ratio (content ratio), property value, and parameter used in the following description can be replaced with upper limit values (numerical values defined as “or less” or “below”) or lower limit values (numerical values defined as “or more” or “above”) of corresponding numerical values in mixing ratio (content ratio), property value, and parameter described in the above-described “DESCRIPTION OF EMBODIMENTS”.

### <Details of Components>

Trade names and abbreviations of each of the components used in Examples and Comparative Examples are described in detail.
jER1007: bisphenol A-type epoxy resin, solid at 25° C., thermoplastic resin, softening point of 128° C., manufactured by Mitsubishi Chemical Group Corporation
jER1009: bisphenol A-type epoxy resin, solid at 25° C., thermoplastic resin, softening point of 144° C., manufactured by Mitsubishi Chemical Group Corporation
jER1010: bisphenol A-type epoxy resin, solid at 25° C., thermoplastic resin, softening point of 150° C. or more, manufactured by Mitsubishi Chemical Group Corporation
UH2170: acrylic resin, solid at 25° C., thermoplastic resin, softening point of 80 to 85° C., manufactured by TOAGOSEI CO., LTD.
jER1004: bisphenol A-type epoxy resin, solid at 25° C., thermoplastic resin, softening point of 97° C., manufactured by Mitsubishi Chemical Group Corporation
jER828: bisphenol A-type epoxy resin, epoxy equivalent of 184 to 194 g/eq, liquid at 25° C., thermosetting resin, manufactured by Mitsubishi Chemical Group Corporation
SnAg: solder particles (96.5% by mass of Sn, 3.5% by mass of Ag, melting point of 221° C., spherical shape, average primary particle size of 3 μm, oxygen concentration of 1100 ppm)
SnAgCu: solder particles (96.5% by mass of Sn, 3.0% by mass of Ag, 0.5% by mass of Cu, melting point of 217 to 219° C., spherical shape, average primary particle size of 3 μm, oxygen concentration of 1100 ppm)
SnBi: solder particles (42% by mass of Sn, 58% by mass of Bi, melting point of 139° C., spherical shape, average primary particle size of 3 μm, oxygen concentration of 1100 ppm)

### <Preparation of Bonding Sheet Composition and Bonding Sheet>

### Examples 1 to 5, Comparative Examples 1 and 2

### [Preparation of Bonding Sheet Composition]

The resin component, the solder particles, and the flux were mixed in accordance with mixing formulations described in Table 1 to be added to methyl ethyl ketone (MEK), thereby preparing the bonding sheet composition (solid content concentration of 70% by mass). As the flux, a solution of the flux obtained by adding malic acid to ethanol to be dissolved (solid content concentration of 30% by mass) was used.

### [Preparation of Bonding Sheet]

### (Preparation Step)

The release liner was prepared.

### (Disposition Step)

The bonding sheet was disposed on one surface of the release liner in the thickness direction. Specifically, a varnish of the bonding sheet composition was coated onto one surface of the release liner in the thickness direction to be dried. The drying temperature was 60° C., and the drying time was 5 minutes. Thus, the bonding sheet (thickness of 5 μm) was prepared on one surface of the release liner in the thickness direction.

### <Fabrication of Electrode for Evaluation>

Each of the bonding sheets of Examples and Comparative Examples was attached to a substrate having a plurality of simulated electrodes (cylindrical electrode, diameter of 15 μm, height of 1 μm, electrode pitch (=distance between the centers) of 30 μm), and the release liner was peeled. Next, the substrate was disposed on a hot plate which was heated at 40° C. in advance, and thereafter, the temperature thereof was increased to 260° C. (in Example 5, 170° C.) at a temperature rising rate of 20° C./sec., and the temperature thereof was kept for 5 seconds. Thereafter, the resulting substrate was subjected to heat dissipation and cooling again until 40° C. Thus, an electrode for evaluation was fabricated.

### <Evaluation>

### [Viscosity of Resin Component at Time of Melting of Solder Particles]

As for Examples and Comparative Examples, the viscosity of the resin component when the solder particles were melted was measured. Specifically, measurement was carried out using a rheometer (trade name: “MCR302e”, manufactured by Anton Paar GmbH) under the conditions of the temperature rising rate of 10° C./min., strain of 0.05%, and a frequency of 1 Hz. Each of the sheets having a thickness of 300 μm and consisting of only the resin components of Examples 1 to 5 and Comparative Examples 1 and 2 was fabricated, and the measurement was carried out using a jig of @12 mm. The results are shown in Table 1.

### [Average Secondary Particle Size of Solder Particles]

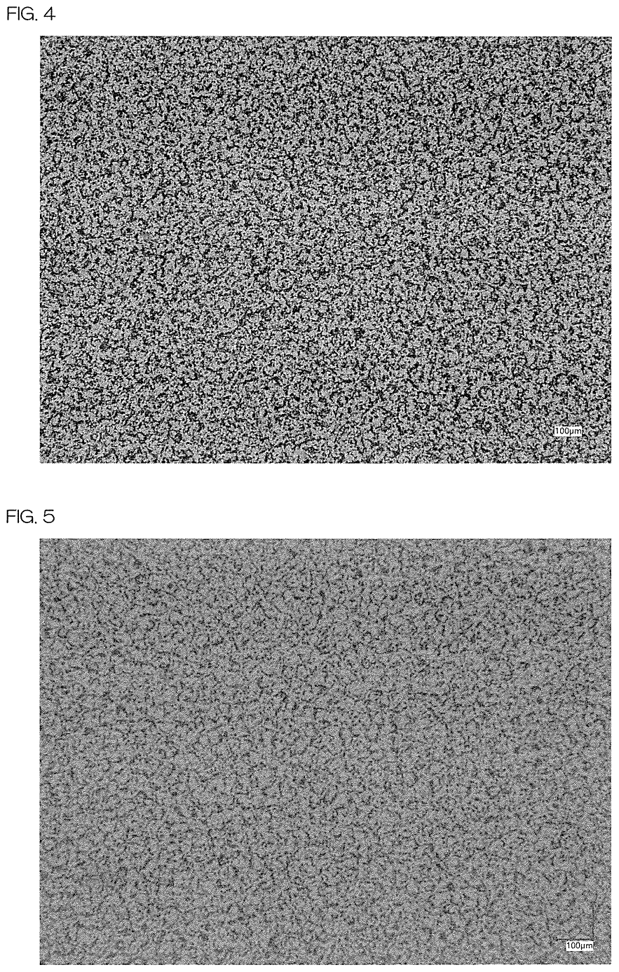

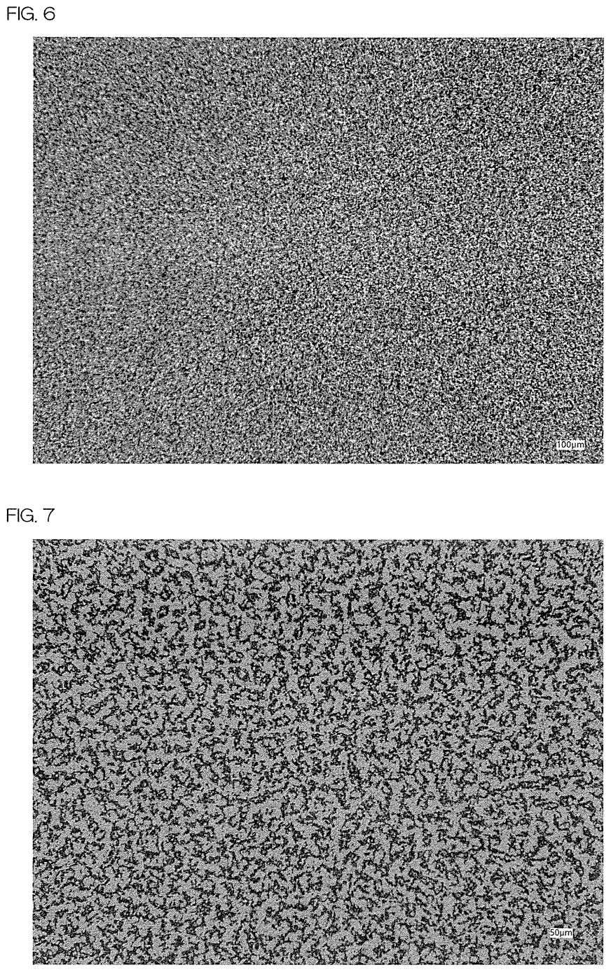

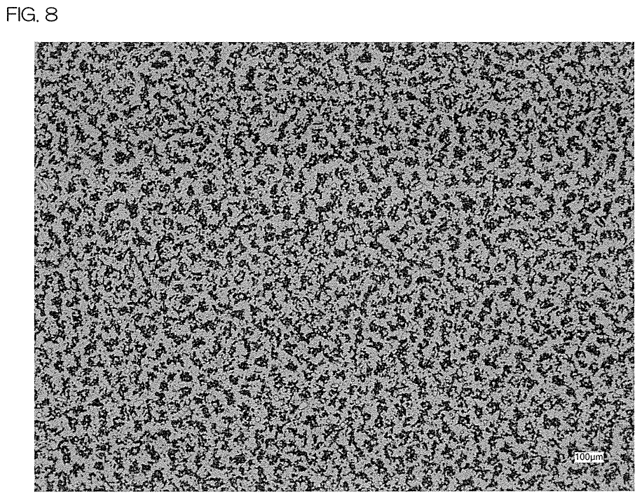

Each of the bonding sheets of Examples and Comparative Examples was observed at a magnification of 1000 times using a digital microscope (trade name: “VHX-8000”, manufactured by KEYENCE CORPORATION), and a still image was photographed. A part of the results is shown in FIGS. 4 to 8. Specifically, FIG. 4 shows Example 1, FIG. 5 shows Example 2, FIG. 6 shows Example 3, FIG. 7 shows Comparative Example 1, and FIG. 8 shows Comparative Example 2.

Next, the obtained still image was binarized using a “Threshold” function of an image processing software “imageJ, developed by Wayne Rasband (NIH)”. An arbitrary straight line was drawn from one side of the photographed image to the corresponding one side as for the image subjected to the binarization, and a gray scale display was carried out on pixels on the line. The number of pixels was counted as for each of the portions continuously showing a value of 255 in gray scale notation. The number of pixels of a length of a scale bar (100 μm) in the image was counted, and by normalizing with it, the secondary particle size of the solder particles was determined from each of the portions continuously showing the value of 255 in the gray scale notation, and the average secondary particle size of the solder particles was calculated by averaging these. The results are shown in Table 1.

### [Generation of Bridge]

As for each of the electrodes for evaluation of Examples and Comparative Examples, a presence or absence of bridges connecting between the electrodes adjacent to each other was observed using a digital microscope (trade name: “VHX-8000”, manufactured by KEYENCE CORPORATION, magnification of 500 times). A generation of the bridge was evaluated based on the following criteria. The results are shown in Table 1.

### {Criteria}

◯: The generation of the bridge was 1% or less of the total.
x: The generation of the bridge was above 1% of the total.

### [Observation of Solder Portion]

As for each of the electrodes for evaluation of Examples and Comparative Examples, a state of integration with respect to the electrode was observed using the digital microscope (trade name: “VHX-8000”, manufactured by KEYENCE CORPORATION, magnification of 500 times). The integration with respect to the electrode was evaluated based on the following criteria. The results are shown in Table 1.

{Criteria}
◯: A ratio of a portion where a half or more of the electrode was not covered with the solder particles was below 1% of the total.
x: A ratio of a portion where a half or more of the electrode was not covered with the solder particles was 1% or more of the total.

### [Confirmation of Non-Integrated Solder Particles]

As for each of the electrodes for evaluation of Examples and Comparative Examples, the number of solder particles which was not integrated in the electrode was measured using the digital microscope (trade name: “VHX-8000”, manufactured by KEYENCE CORPORATION, magnification of 500 times). The non-integrated solder particles were evaluated based on the following criteria. The results are shown in Table 1.

### {Criteria}

Nearly absence: The number of non-integrated solder particles was 100 or less per 100×100 μm².
Slightly presence: The number of non-integrated solder particles was above 100 and 200 or less per 100×100 μm².
Presence: The number of non-integrated solder particles was above 200 per 100×100 μm².

TABLE 1

| | | | | | | | | | Comparative | Comparative |
|---|---|---|---|---|---|---|---|---|---|---|
| Ex.•Comp. Ex. No. | | | | Ex. 1 | Ex. 2 | Ex. 3 | Ex. 4 | Ex. 5 | Ex. 1 | Ex. 2 |
| Bonding | Resin | Thermoplastic | jER1007 | 50 | — | — | 50 | 50 | — | — |
| Sheet | Component | Resin | jER1009 | — | 50 | — | — | — | — | — |
| | | | jER1010 | — | — | 50 | — | — | — | — |
| | | | UH2170 | — | — | — | — | — | 50 | — |
| | | | jER1004 | — | — | — | — | — | — | 50 |
| | | Thermosetting | jER828 | 50 | 50 | 50 | 50 | 50 | 50 | 50 |
| | | Resin | | | | | | | | |

| Solder Particles | SnAg | 150 | 150 | 150 | — | — | 150 | 150 |
|---|---|---|---|---|---|---|---|---|
| | SnAgCu | — | — | — | 150 | — | — | — |
| | SnBi | — | — | — | — | 150 | — | — |
| Flux (Solid Content) | Malic Acid | 15 | 15 | 15 | 15 | 15 | 15 | 15 |

| | Softening Point of Thermoplastic Resin (° C.) | | 128 | 144 | 150 or more | 128 | 128 | 80 to 85 | 97 |
|---|---|---|---|---|---|---|---|---|---|
| Evaluation | Average Secondary Particle Size | | 4.9 | 4.3 | 4.2 | 4.9 | 4.9 | 15.4 | 8.5 |
| | of Solder Particles (μm) | | | | | | | | |
| | Viscosity of Resin Component at Time | | 300 | 700 | 1500 | 300 | 1700 | 200 | 300 |
| | of Melting of Solder Particles (mPa ·s) | | | | | | | | |
| | Reliability | Generation of Bridge | ∘ | ∘ | ∘ | ∘ | ∘ | x | x |
| | | Observation of | ∘ | ∘ | ∘ | ∘ | ∘ | x | x |
| | | Solder Portion | | | | | | | |
| | Productivity | Confirmation of Non- | Nearly | Slightly | Presence | Nearly | Presence | Nearly | Nearly |
| | | Integrated Solder Particles | Absence | Presence | | Absence | | Absence | Absence |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The bonding sheet of the present invention is preferably used in bonding between terminals of two wiring circuit boards disposed spaced apart in a thickness direction.

### DESCRIPTION OF REFERENCE NUMERALS

1 Bonding sheet
5 Solder particles

1. A bonding sheet comprising:
a resin component and a solder particle, wherein
both an average primary particle size of the solder particle and an average secondary particle size of the solder particle are 7 μm or less.

2. The bonding sheet according to claim 1 further comprising flux.

3. The bonding sheet according to claim 1, wherein
the resin component includes a thermoplastic resin, and
the thermoplastic resin has a softening point of 110° C. or more.

4. The bonding sheet according to claim 1, wherein
the viscosity of the resin component at a melting point of the solder particle is 5000 mPa·s or less.

5. The bonding sheet according to claim 1, wherein
the resin component includes a thermoplastic resin and a thermosetting resin,
the thermoplastic resin is solid at 25° C., and
the thermosetting resin is liquid at 25° C.

6. The bonding sheet according to claim 1, wherein
both the average primary particle size of the solder particle and the average secondary particle size of the solder particle are 5 μm or less.

7. The bonding sheet according to claim 1, wherein
the bonding sheet has a thickness of 15 μm or less.

8. The bonding sheet according to claim 2, wherein
the bonding sheet has a thickness of 15 μm or less.

9. The bonding sheet according to claim 3, wherein
the bonding sheet has a thickness of 15 μm or less.

10. The bonding sheet according to claim 4, wherein
the bonding sheet has a thickness of 15 μm or less.

11. The bonding sheet according to claim 5, wherein
the bonding sheet has a thickness of 15 μm or less.

12. The bonding sheet according to claim 6, wherein
the bonding sheet has a thickness of 15 μm or less.
